(19) United States
(12) Patent Application Publication
(10) Pub. No.: US 2025/0176202 A1
(43) Pub. Date: May 29, 2025

(54) Compound Semiconductor Device for High Power and High Frequency Operation

(71) Applicant: Mitsubishi Electric Research Laboratories, Inc., Cambridge, MA (US)

(72) Inventors: Koon Hoo Teo, Lexington, MA (US); Nadim Chowdhury, Cambridge, MA (US)

(73) Assignee: Mitsubishi Electric Research Laboratories, Inc., Cambridge, MA (US)

(21) Appl. No.: 18/523,477

(22) Filed: Nov. 29, 2023

(51) Int. Cl. H01L 29/737; H01L 29/20; H01L 29/417; H01L 29/423; H01L 29/66; H01L 29/778

(52) U.S. Cl. CPC H10D 10/891; H10D 10/021; H10D 30/015; H10D 30/475; H10D 64/251; H10D 64/281; H10D 62/8503

(57) ABSTRACT

A compound transistor comprises a plurality of electrodes, a first semiconductor structure, and a second semiconductor structure. The electrodes include a source, a gate, and a drain of a first transistor. The first semiconductor structure is electrically connected to the plurality of electrodes and includes a barrier layer and a first channel layer. The second semiconductor structure includes a second channel layer, a buffer layer, and a substrate layer arranged such that the buffer layer is sandwiched between the second channel layer and the substrate layer. The second transistor structure supports the first semiconductor structure such that a connecting layer is arranged between the first and the second semiconductor structures. A source electrode is electrically connected to the second channel layer such that the source of the first transistor forms a base of a second transistor, and the source electrode forms a collector of the second transistor.

### TECHNICAL FIELD

The present disclosure relates generally to semiconductor devices, and more particularly to a compound semiconductor device for high power and high frequency operations.

### BACKGROUND

Combining transistors for new applications or for achieving enhancements in performance parameters is often desired in many scenarios. For example, in order to have a good integration of analog and digital functions on the same chip, Bipolar CMOS (BiCMOS) has been a preferred approach. BiCMOS technology combines the features of both bipolar junction transistors (BJTs) and complementary metal-oxide-semiconductor (CMOS) transistors in a single integrated circuit (IC). It integrates both types of transistors to leverage their respective advantages and achieve improved performance characteristics. In BiCMOS technology, the bipolar transistors provide high-speed and high-current capabilities, while the CMOS transistors offer low power consumption and compatibility with digital logic circuits. By combining these two technologies, BiCMOS provides a balance between high-speed analog functionality and low-power digital capabilities.

The bipolar transistors in BiCMOS technology are typically used for analog and high-speed applications, such as amplification, filtering, and high-frequency signal processing. They offer high gain, low noise, and good linearity, making them suitable for analog circuitry. On the other hand, the CMOS transistors in BiCMOS technology are used for digital logic and low-power circuitry. CMOS technology is known for its low power consumption, high noise immunity, and compatibility with digital circuit design. By incorporating CMOS transistors alongside bipolar transistors, BiCMOS technology enables the integration of analog and digital functions on the same chip.

For these reasons, BiCMOS technology finds applications in a wide range of electronic devices, including communication systems, data converters, high-speed processors, mixed-signal ICs, and wireless devices. It offers the advantages of both bipolar and CMOS technologies, allowing designers to achieve higher levels of integration, improved performance, and optimized power consumption in their circuits. However, BiCMOS technology has its own drawbacks and is not suitable for many applications such as switching, amplification and the like due to limitations on the power and frequency handling capabilities. On the other hand, a High Electron Mobility Transistor (HEMT) is capable of providing efficient current flows at high voltages. Additionally, HEMT devices can operate at higher temperatures than BiCMOS due to the wide bandgap of III-N materials used in HEMTs. Furthermore, HEMTs are highly suitable for high frequency operations. As such, High Electron Mobility Transistors are a promising class of semiconductor devices that offer high power and high-frequency performance. Their wide bandgap, high electron mobility, and low capacitance make them well-suited for a wide range of applications, including wireless communication systems and power electronics.

A HEMT has a high-power density due to high electron mobility provided by an underlying two-dimensional electron gas (2-DEG) channel. The 2-DEG channel has a high electron mobility, which allows for efficient current flow at high voltages. This enables a HEMT device to handle high power levels while maintaining a low on-resistance. Additionally, the wide bandgap of some III-N materials such as GaN allows for high-temperature operation, which is important for many applications, including wireless communication systems and power electronics.

Despite these significant advantages, HEMTs suffer from the drawback of high knee voltage or cut-in voltage which is the forward voltage at which the current through a semiconductor junction begins to rapidly increase. Thus, knee voltage is the minimum amount of voltage required for conduction through a junction in a transistor. The forward voltage at which the current through the PN junction starts increasing rapidly is referred to as knee voltage. The knee voltage is important because it reduces Vₘₐₓ, thereby reducing power capacity and, in effect, the power-added efficiency (PAE) in a device. In principle, GaN-channel HEMTs offer lower Vₖₙₑₑ than AlGaN-channel HEMTs due to a higher p for the former. The high knee voltage of the HEMT significantly limits the available output power from the HEMT device, thereby limiting the applicability and usage of the HEMT device.

### SUMMARY

Example embodiments described herein are directed towards an improved HEMT structure, devices based on the improved HEMT structure, and methods of manufacturing thereof. Some example embodiments provide a compound semiconductor configuration comprising a HEMT and a bipolar junction transistor (BJT) grown on a common substrate. The BJT assists the HEMT's output thereby providing low knee voltage requirements for the overall device. The compound semiconductor device exhibits a high current carrying capability with low knee voltage requirements. Such an arrangement of the transistors allows for a much higher drain current, and a higher input impedance compared to a single bipolar transistor configuration. The compound semiconductor device finds application in a wide array of use cases, some non-limiting examples of which include amplifiers, power supplies, and other applications where high current and high input impedance and higher switching speed are desirable.

It is an object of some embodiments to extend the principles of BiCMOS technology to the technical area of HEMTs. Some embodiments are based on recognizing that principles behind BiCMOS technology can be used to address some problems of the HEMT industry while principles behind HEMTs can address some disadvantages of the BiCMOS technology rooted in the CMOS transistors. For example, one of the bottlenecks of GaN HEMT is its high knee voltage of around 5V, which limits the available output power of a power amplifier. Some embodiments are based on the recognition that a bipolar junction transistor at the output of the HEMT reduces the knee voltage. On the other hand, the principles of HEMT can be used to reduce the cost of mass production of such transistors.

However, to take advantage of the synergy of such an extension, there is a need to modify the principles of implementation of BiCMOS technology. This is because a bipolar junction transistor (BJT) forming a part of the BiCMOS technology is a type of transistor that uses both electrons and electron holes as charge carriers. In contrast, a field-effect transistor (FET) is a unipolar transistor that uses only one kind of charge carrier. Because the HEMT is a field effect transistor (FET) that uses an electric field to control the flow of current in a heterojunction formed in a semiconductor, the principles of HEMT are in sharp contrast to the principles of BiCMOS.

Some embodiments are based on recognizing that the principles of BiCMOS technology can be captured by a two-transistor model providing an abstraction from the implementation details of the BiCMOS device. Some embodiments are based on recognizing that the layered structure of a semiconductor device can be designed to mimic an electrical circuit diagram of the two-transistor model with different principles of physics than the principles of BiCMOS technology. Out testing, experimentation, and simulation demonstrate that emulating the principles of the two-transistor model using the physics of the semiconductor structure designed according to embodiments brings the benefits of the BiCMOS and HEMT in synergy.

Accordingly, some example embodiments are directed towards a semiconductor structure that houses the BJT and the HEMT on a common substrate. In order to enhance performance of such a device and to simplify the manufacturing process, some example embodiments allow sharing of a semiconductor layer between the BJT and the HEMT in such a semiconductor structure. For example, an n-p-n BJT requires two layers of n-doped layers sandwiching a p-doped layer in between. When layers of a BJT are laterally arranged, doping the layers according to the desired charge carrier type may be straightforward and thus relatively easier. However, when the layers of the BJT are vertically stacked on each other, selectively doping the layers is a challenging task and makes the manufacturing of such a structure difficult. Some example embodiments alleviate this problem by allowing the BJT to share the channel layer of the HEMT such that in an on state of the HEMT, the accumulation of a two-dimensional gas in the channel layer makes the channel layer an n-doped layer for the BJT. Such layer sharing removes the burden of separately doping each layer thereby simplifying the structure. Also, due to the layer sharing, the overall structure is smaller and thus economically and functionally superior.

In order to achieve the aforementioned objectives and improvements, some example embodiments provide a compound transistor, an apparatus embodying such a compound structure and a method of manufacturing such a compound transistor.

Some example embodiments provide a compound transistor comprising a plurality of electrodes, a first semiconductor structure, and a second semiconductor structure arranged and electrically connected in a manner described with reference to various embodiments. The electrodes include a source, a gate, and a drain of a first transistor. The first semiconductor structure is electrically connected to the plurality of electrodes and includes a barrier layer and a first channel layer. The barrier layer and the first channel layer comprise materials forming heterojunction for carrying a charge between the source and the drain in the first transistor. The second semiconductor structure includes a second channel layer, a buffer layer, and a substrate layer arranged such that the buffer layer is sandwiched between the second channel layer and the substrate layer. The second transistor structure is arranged to support the first semiconductor structure such that a connecting layer is arranged between the first and the second semiconductor structures. A source electrode is electrically connected to the second channel layer of the second semiconductor structure such that the source of the first transistor forms a base of a second transistor, and the source electrode forms a collector of the second transistor.

The source of the first transistor has a structure defined by a first leg and a second leg, where the first leg is connected to the second leg and is parallel to a longitudinal extension of the drain. The second leg is parallel to a longitudinal extension of the source electrode. The first leg of the source may be connected to the second leg with a step such that the first leg is arranged in a first plane that lies at the top of the first semiconductor structure, and the second leg is connected to the first leg in a second plane that lies at the bottom of the first semiconductor structure and is on the connecting layer. In some cases, width of the connecting layer may be greater than a width of the first semiconductor structure such that the connecting layer supports the second leg. In some cases, width of the second semiconductor structure may be greater than the width of the connecting layer such that the second semiconductor structure supports the source electrode.

According to some example embodiments, a work-function (WF) of a material of the connecting layer may be greater than a WF of a material of the first channel layer and a WF of a material of the second channel layer. In some example embodiments, at least one dimension of the second semiconductor structure may be greater than a width of the first semiconductor structure.

Some example embodiments provide an apparatus comprising a high electron mobility transistor and a bipolar junction transistor. The HEMT comprises a barrier layer and a channel layer such that there is an accumulation of two-dimensional gas (2-DEG) at an interface of the barrier layer and the channel layer in an on state of the HEMT. The BJT is structurally coupled to the HEMT such that a source of the HEMT is electrically coupled to a base of the BJT and the channel layer of the HEMT forms an emitter layer of the BJT.

The accumulation of the 2-DEG causes doping of the channel layer of the HEMT with charge carriers thereby forming the emitter layer of the BJT. The HEMT and the BJT have a common substrate layer. The HEMT is formed as a first multi-layered semiconductor structure and the BJT is formed as a second multi-layered semiconductor structure with the channel layer commonly shared between the first multi-layered semiconductor structure and the second multi-layered semiconductor structure. As such, the second multi-layered semiconductor structure is directly on top of the common substrate layer and the first multi-layered semiconductor structure is directly on top of the second multi-layered semiconductor structure.

According to some example embodiments, the drain of the HEMT is electrically coupled to a collector of the BJT. The HEMT may be operable to provide an input current at the source in the on state of the HEMT and provide zero current at the source in an off state of the HEMT. The BJT may be operable to amplify the input current in an on state of the BJT.

### BRIEF DESCRIPTION OF THE DRAWINGS

The presently disclosed embodiments will be further explained with reference to the following drawings. The drawings shown are not necessarily to scale, with emphasis instead generally being placed upon illustrating the principles of the presently disclosed embodiments.

FIG. 1A illustrates a three-dimensional structure of a compound transistor, according to some example embodiments;

FIG. 1B illustrates a cross-sectional view of the compound transistor of FIG. 1A, according to some example embodiments;

FIG. 1C illustrates a top view of the compound transistor of FIG. 1A, according to some example embodiments;

FIG. 1D illustrates a three-dimensional view of a high electron mobility transistor (HEMT) of the compound transistor of FIG. 1A, according to some example embodiments;

FIG. 1E illustrates a cross sectional view of the HEMT of FIG. 1D, according to some example embodiments;

FIG. 1F illustrates a three-dimensional structure of a bipolar junction transistor (BJT) of the compound transistor of FIG. 1A, according to some example embodiments;

FIG. 1G illustrates a cross sectional view of the BJT of FIG. 1F, according to some example embodiments;

FIG. 2A illustrates a two-transistor model of the compound transistor of FIG. 1A, according to some example embodiments;

FIG. 2B illustrates a circuit symbol equivalent of the compound transistor of FIG. 1A, according to some example embodiments;

FIG. 3 illustrates circuit diagram of an inverter realized using the compound transistor of FIG. 2B, according to some example embodiments;

FIG. 4 illustrates circuit diagram of a power amplifier realized using the compound transistor of FIG. 2B, according to some example embodiments;

FIG. 5A illustrates a flowchart of a method of manufacturing the compound transistor of FIG. 1A, according to some example embodiments; and

FIG. 5B illustrates a fabrication process of the compound transistor of FIG. 1A, according to some example embodiments.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like-reference numbers and designations in the various drawings may indicate like elements.

The semiconductor industry utilizes various methods and structures to form high electron mobility (HEM) semiconductor devices. For high power, high temperature, and/or high frequency applications, devices formed in wide bandgap semiconductor materials such as the Group III nitrides are often used. These materials typically have higher electric field breakdown strengths and higher electron saturation velocities. Hence some embodiments of such devices utilize layers of materials selected from group III or group V of the periodic table of elements. In some specialized applications compound semiconductor materials may also be used for the layers. The selected materials are sometimes arranged to form a heterojunction between two of the semiconductor materials. For example, the semiconductor materials could use layers of gallium nitride (GaN) or aluminum gallium nitride (AlGaN). AlGaN/GaN HEMTs are an emerging class of semiconductor devices that offer high power and high-frequency performance. HEMTs are a type of field-effect transistor (FET) that use a two-dimensional electron gas (2-DEG) to conduct current. In some applications, the HEM device may be a transistor often referred to as a HEM transistor (HEMT). HEMT devices may offer operational advantages in a number of applications. In operation, a 2-DEG is formed in a HEMT device at the heterojunction of two semiconductor materials with different bandgap energies, where the smaller bandgap material has a higher electron affinity. The 2-DEG creates a large conduction band discontinuity which allows the 2-DEG to be highly confined, resulting in a high electron mobility and a low resistance. The 2-DEG is an accumulation layer in the smaller bandgap material and can contain a very high sheet electron concentration. Additionally, electrons that originate in the wider-bandgap semiconductor material transfer to the 2-DEG layer, allowing a high electron mobility due to reduced ionized impurity scattering. This combination of high carrier concentration and high carrier mobility can give the HEMT a very large transconductance.

HEMTs fabricated in Group Ill-nitride based material systems have the potential to generate large amounts of radio frequency (RF) power because of the combination of material characteristics that includes the aforementioned high breakdown fields, wide bandgaps, large conduction band offset, and/or high saturated electron drift velocity. Thus, HEMT device may be advantageously utilized in specialized applications such as a power amplifier (PA). Power amplifiers, including power amplifiers utilizing HEMT devices, often experience a trade-off between output power and bandwidth. Internal inefficiencies, such as parasitic capacitances, can impact the switching speed of the device. Smaller transistor geometries can achieve higher operating frequencies, but the smaller dimensions may result in reduced current (and power) capacity.

The AlGaN/GaN HEMT structure consists of several layers of materials grown on a substrate, typically a sapphire or silicon carbide wafer or a Coefficients of Thermal Expansion (CTE) matched—AlN material. The layers include a buffer layer, a GaN layer, an AlGaN layer, and a gate electrode. The buffer layer is used to reduce defects in the crystal structure of the substrate, which can degrade the performance of the device. The GaN layer provides the 2-DEG channel, and the AlGaN layer is used to tune the properties of the channel. The gate electrode is used to control the flow of current through the channel. When a voltage is applied to the gate electrode, it creates an electric field that modulates the density of the 2-DEG and the resistance of the channel. This allows the device to act as a switch or an amplifier, depending on the application.

One of the key advantages of AlGaN/GaN HEMTs is their high-power density. The 2DEG channel has a high electron mobility, which allows for efficient current flow at high voltages. This enables the device to handle high power levels while maintaining a low on-resistance. Additionally, the wide bandgap of the GaN material allows for high-temperature operation, which is important for many applications, including wireless communication systems and power electronics. Another advantage of AlGaN/GaN HEMTs is their high-frequency performance. The 2DEG channel has a low capacitance, which allows for fast switching speeds and high-frequency operation. This makes the device well-suited for use in radio frequency (RF) amplifiers and other high-frequency applications. Accordingly, AlGaN/GaN HEMTs have a wide range of potential applications. They are used in wireless communication systems, such as cellular base stations and satellite communication systems, due to their high power and high-frequency performance. They are also being used in power electronics applications, such as DC-DC converters and inverters, due to their high-power density and high-temperature operation. Additionally, AlGaN/GaN HEMTs have potential applications in sensing, imaging, and lighting. In conclusion, AlGaN/GaN High Electron Mobility Transistors are a promising class of semiconductor devices that offer high power and high-frequency performance. Their wide bandgap, high electron mobility, and low capacitance make them well-suited for a wide range of applications, including wireless communication systems and power electronics.

However, one of the major bottlenecks of GaN HEMT is its high knee voltage of around 5V, which significantly limits the available output power of an end use device such as a power amplifier. Attempts to mitigate this problem have met with increased wafer size or limitations on other performance metrics for the transistor device. Accordingly, resulting from meticulous experimentations, some example embodiments propose a compound transistor device that has high current carrying capability with low knee voltage. According to some example embodiments, low knee voltage has been achieved through the use of bipolar junctions at the output of the HEMT device on the same substrate.

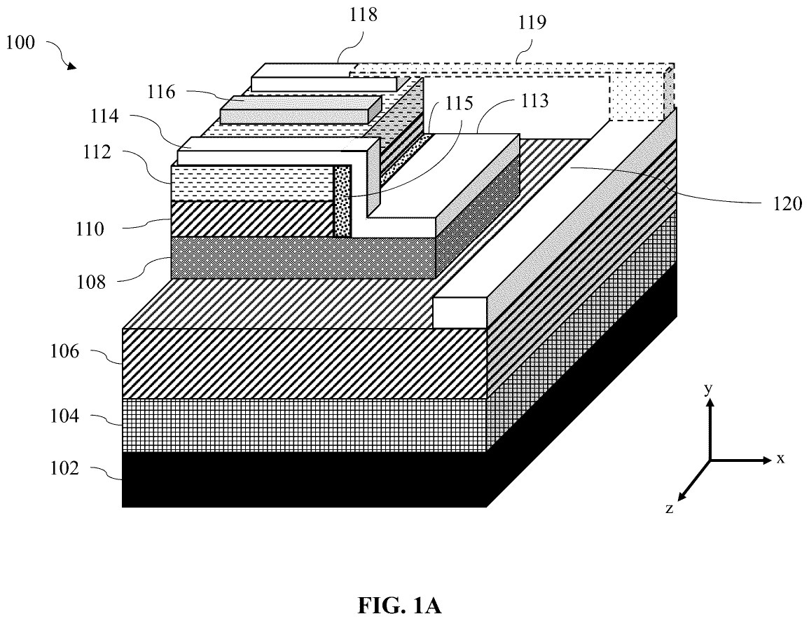

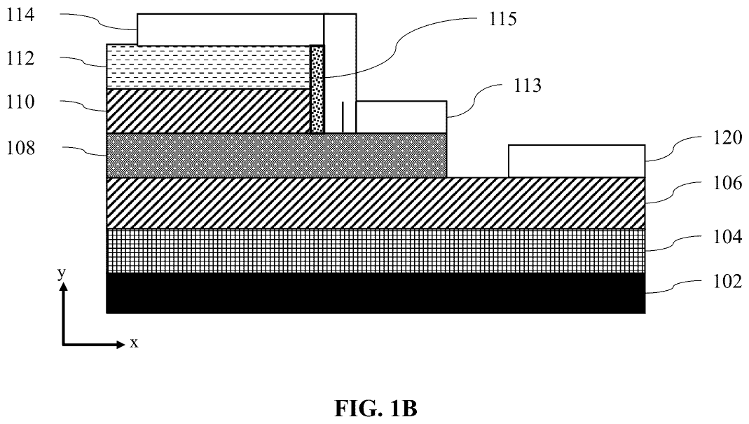

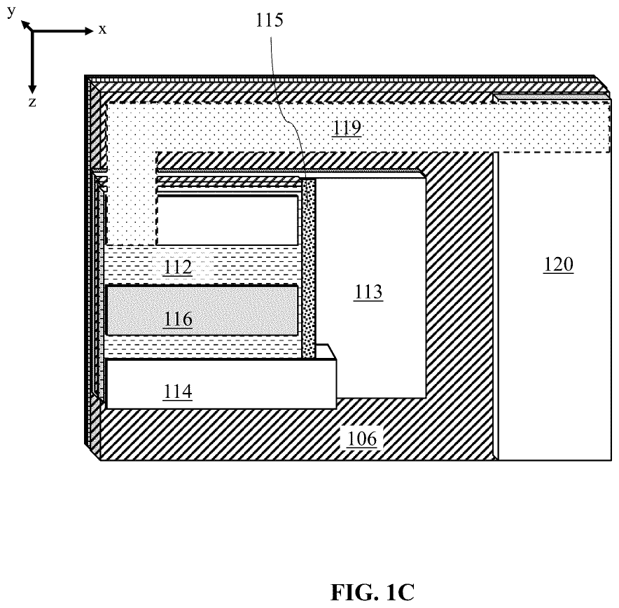

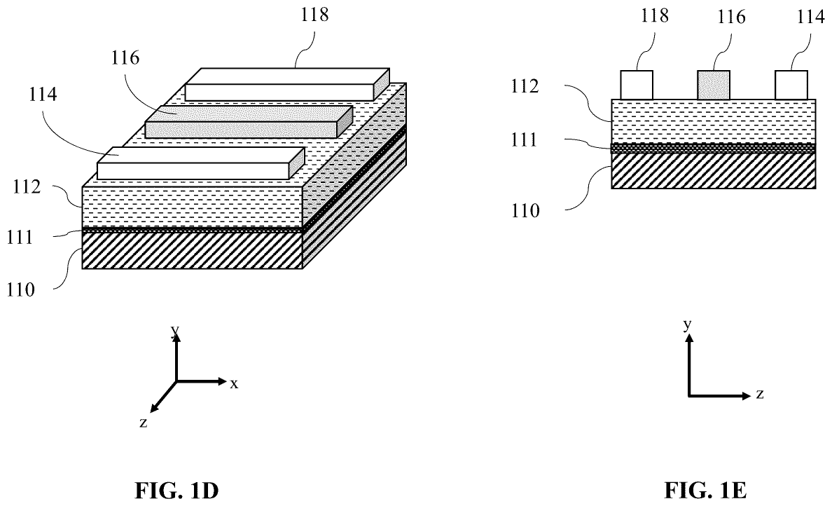

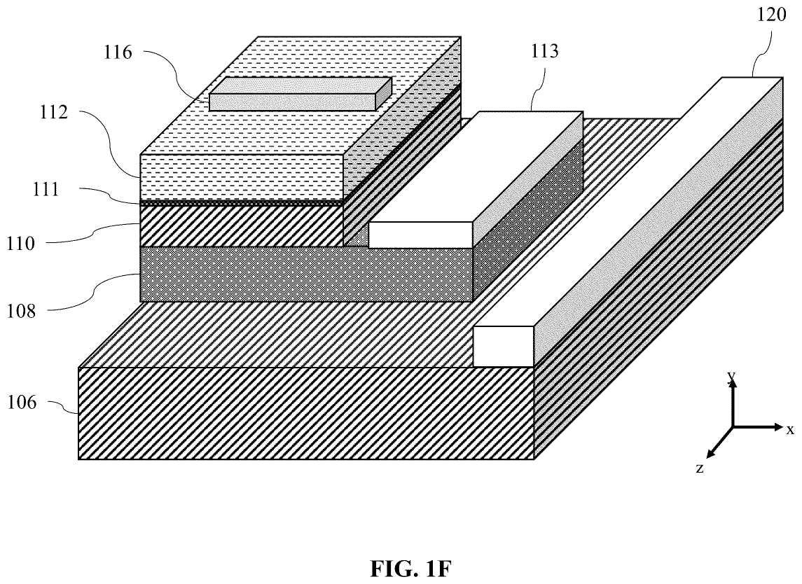

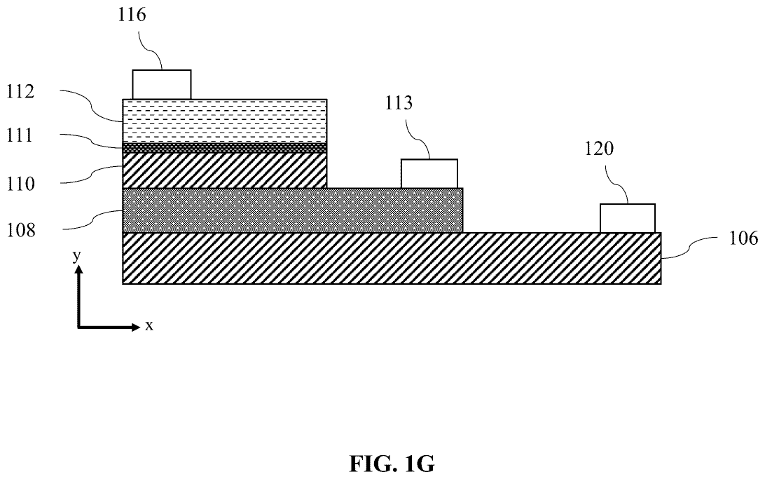

FIG. 1A illustrates a three-dimensional structure of a compound transistor 100, according to some example embodiments. The compound transistor 100 has a structure spread across three orthogonal planes of a cartesian system such as one defined by x-axis, y-axis, and z-axis. For the sake of simplicity, the stacking of layers of the compound transistor 100 may be considered to be along a vertical y-axis, the span of each layer along a latitudinal and longitudinal plane may be considered to be along x and z axes, respectively. FIG. 1B illustrates a cross-sectional view of the compound transistor 100, according to some example embodiments. The cross section of the compound transistor 100 corresponds to the view of the transistor 100 as seen in the xy plane. FIG. 1C illustrates a top view of the compound transistor 100, according to some example embodiments. The top view corresponds to the visualization of the transistor 100 from along the y direction. FIGS. 1A-1C will now be described in conjunction with each other.

Referring to FIG. 1A, the compound transistor 100 comprises a substrate layer 102 which may be, for example, a silicon carbide SiC substrate or a sapphire substrate. The substrate 102 may be a semi-insulating silicon carbide (SiC) substrate that may be, for example, the 4H polytype of silicon carbide. Other silicon carbide candidate polytypes may include the 3C, 6H, and 15R polytypes. The substrate may be a High Purity Semi-Insulating (HPSI) substrate. Although silicon carbide may be used as a substrate material, some example embodiments may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), Lanthanum aluminate (LaAlO₃, abbreviated as LAO), indium phosphide (InP), and the like. The substrate 102 may be a silicon carbide wafer, and the compound transistor 100 may be formed, at least in part, via wafer-level processing, and the wafer may then be diced to provide a plurality of individual compound transistors 100. The substrate 102 may have a lower surface and an upper surface. In some embodiments, the substrate 102 may be a thinned substrate. In some embodiments, the thickness of the substrate 102 along the vertical y direction may be between 100 μm to 1120 μm.

The compound transistor 100 also comprises a buffer layer 104 on the substrate 102. The buffer layer 104 may be grown to tackle the lattice mismatch between the wafer material and the III-N semiconductor. The buffer layer 104 may be formed by a deposition process, such as metal-organic chemical vapor deposition (MOCVD), molecular beam epitaxy (MBE), or liquid phase epitaxy (LPE), the like, or a combination thereof. According to some example embodiments, the buffer layer 104 includes one or a combination of C-doped GaN, Fe-doped GaN material. In some embodiments, the thickness of the buffer layer 104 along the vertical y direction may be 2-4 μm.

As is shown in FIGS. 1A and 1B, the compound transistor also comprises a second channel layer 106 over the buffer layer 104. The second channel layer 106 may comprise a suitable III-N semiconductor material such as gallium nitride (GaN). In some embodiments, the thickness of the second channel layer 106 along the vertical y direction may be around or equal to 100 nm. Referring to FIG. 1B, along the y-direction, the second channel layer 106 may have a bottom surface in contact with the buffer layer 104 and a top surface opposite to the bottom surface. On one side of the top surface of the second channel layer 106, a collector metal contact 120 may be grown using any suitable process. In some example embodiments, the collector metal contact 120 may extend laterally in a plane of the top surface of the second channel layer 106. In some alternative embodiments, the collector metal contact 120 may extend vertically into the second channel layer 106 such that the collector metal contact 120 is orthogonal to the top surface of the second channel layer 106 as is shown in FIG. 1B. Other suitable configurations may also be possible within the scope of the disclosure. For example, the collector metal contact 120 may extend through the bottom surface of the second channel layer 106 towards the top surface of the second channel layer 106.

On another side of the top surface of the second channel layer 106, a connecting layer 108 is grown. The connecting layer 108 may comprise a suitable p-doped 111-N semiconductor material such as p-GaN. In some embodiments, the thickness of the connecting layer 108 along the vertical y direction may be 100-200 nm. A surface of the connecting layer 108 that interfaces the top surface of the second channel layer 106 may have a dimension that is less than that of the top surface of the second channel layer 106 such that the connecting layer 108 is always not in direct contact with the collector metal contact 120.

The compound transistor 100 also comprises a HEMT structure defined by a first channel layer 110 and a barrier layer 112 that is grown on top of the connecting layer 108. The first channel layer 110 comprises any suitable 111-N semiconductor material such as gallium nitride (GaN). The barrier layer 112 may comprise AlGaN. In some embodiments, the thickness of the first channel layer 110 along the vertical y direction may be 20-50 nm while that of the barrier layer 112 along the vertical y direction may be 10-20 nm. Such a HEMT structure, defined by the first channel layer 110 and a barrier layer 112, may have a bottom surface that is in contact with the connecting layer 108 on the channel layer side and a top surface on the barrier layer side that is opposite to the bottom surface. As is shown in FIG. 1A and particularly in FIGS. 1B and 1C, a dimension of the bottom surface of the HEMT structure in the xz plane is always less than that of the top surface of the connecting layer in the xz plane such that the first channel layer 110 only covers a first portion of the connecting layer 108. A base metal contact 113 is grown on a second portion of the connecting layer 108. The HEMT structure also comprises a plurality of electrodes such as one electrode each for a source 114, a gate 116, and a drain 118 of the HEMT structure.

According to some example embodiments, the drain electrode 118 may be optionally connected to the collector metal contact 120 using a via connect 119 as shown in FIGS. 1A and 1C. In some example embodiments, the source electrode 114 of the HEMT is connected to the base metal contact 113. In this regard, as is shown in FIGS. 1A and 1B, the source electrode 114 connected to the base metal contact 113 together defines or comprises a structure having a first leg and a second leg, where the first leg is connected to the second leg by a step. Referring to FIG. 1A, the source electrode 114 may be considered to be the first leg and may be parallel to a longitudinal extension of the drain 118 along x-axis and the second leg may be considered to be the base metal contact 113 and may be orthogonal to a lateral extension of the source electrode 114. The first leg (i.e., the source electrode 114) may be connected to the second leg (i.e., the base metal contact 113) with a step such that the first leg is arranged in a first plane that lies at the top of the HEMT structure, and the second leg is connected to the first leg in a second plane that lies at the bottom of the HEMT structure and is on the connecting layer.

According to some embodiments, the base metal contact 113 is insulated from the HEMT structure. An example of the insulation may be a suitable oxide layer 115 (for example: SiO₂, Al₂O₃, SiNₓ) sandwiched between the base metal contact 113 and the HEMT structure. In some example embodiments, the dimension of the oxide layer 115 along the y-axis may be less than or equal to the dimension of the first channel layer 110 along the y-axis.

FIG. 1D illustrates a three-dimensional view of the HEMT structure of the compound transistor of FIG. 1A, according to some example embodiments. FIG. 1E illustrates a cross sectional view of the HEMT of FIG. 1D, according to some example embodiments. A first channel layer 110 may be formed on a portion of the upper surface of the connecting layer 108 of FIG. 1A, and a barrier layer 112 may be formed on an upper surface of the first channel layer 110. The first channel layer 110 and the barrier layer 112 may each be formed by epitaxial growth in some embodiments. The first channel layer 110 may have a bandgap that is less than the bandgap of the barrier layer 112 and the first channel layer 110 may also have a larger electron affinity than the barrier layer 112. The first channel layer 110 and the barrier layer 112 may include Group III-nitride based materials. In some embodiments, the first channel layer 110 may be a Group III nitride, such as AlₓGa₁₋ₓN, where 0≤×<1, provided that the energy of the conduction band edge of the first channel layer 110 is less than the energy of the conduction band edge of the barrier layer 112 at the interface between the first channel and barrier layers 110, 112. In certain embodiments, x=0, indicating that the first channel layer 110 is GaN. The first channel layer 110 may also be other Group III-nitrides such as InGaN, AlInGaN or the like. According to some example embodiments, the first channel layer 110 may also be a multi-layer structure, such as a superlattice or combinations of GaN, AlGaN or the like.

In some embodiments, the barrier layer 112 may include one or more materials such as AlN, AlInN, AlGaN, AlInGaN, ScAlN or combinations of layers thereof. The barrier layer 112 may comprise a single layer or may be a multi-layer structure. In particular embodiments of the present invention, the barrier layer 112 may be thick enough and may have a high enough aluminum (Al) composition and doping to induce a significant carrier concentration at the interface between the first channel layer 110 and the barrier layer 112 through polarization effects when the barrier layer 112 is buried under ohmic contact metal. The barrier layer 112 may, for example, be from about 2 nm to about 30 nm thick but is not so thick as to cause cracking or substantial defect formation therein. Barrier layer thicknesses in the range of 15-30 nm may be common. In certain embodiments, the barrier layer 112 may be undoped or doped with an n-type dopant to a concentration less than about 10¹⁹ cm⁻³. In some embodiments, the barrier layer 112 is AlₓGa₁₋ₓN where 0<x<1. In particular embodiments, the aluminum concentration is about 25%. However, in other embodiments of the present invention, the barrier layer 112 comprises AlGaN with an aluminum concentration of between about 5% and less than about 100%. In specific embodiments of the present invention, the aluminum concentration is greater than about 10%. The channel layer 110 and/or the barrier layer 112 may be deposited, for example, by metal-organic chemical vapor deposition (MOCVD), molecular beam epitaxy (MBE), or hydride vapor phase epitaxy (HYPE).

The first channel layer 110 and the barrier layer 112 may together form the HEMT structure. A source contact 114 and a drain contact 118 are formed on an upper surface of the barrier layer 112 and are laterally spaced apart from each other. The source contact 114 and the drain contact 118 may form an ohmic contact to the barrier layer 112. According to some example embodiments, the source contact 114 may be coupled to a reference signal such as, for example, a ground voltage. A metallization layer 217 may be deposited on the via connect and on two adjacent source contacts 114 to electrically connect the two adjacent source contacts 114. The metallization layer may be formed of a conductive metal.

The source contact 114 and the drain contact 118 may include a metal that can form an ohmic contact to a gallium nitride-based semiconductor material. In this regard, suitable metals may include refractory metals, such as Ti, W, titanium tungsten (TiW), silicon (Si), titanium tungsten nitride (TiWN), tungsten silicide (WSi), rhenium (Re), Niobium (Nb), Ni, gold (Au), aluminum (Al), tantalum (Ta), molybdenum (Mo), NiSix, titanium silicide (TiSi), titanium nitride (TiN), WSiN, Pt and the like. In some embodiments, the source contact 114 may be an ohmic source contact. Thus, the source contact 114 and the drain contact 118 may contain an ohmic contact portion in direct contact with the barrier layer 112. In some embodiments, the source contact 114 and/or the drain contact 118 may be formed of a plurality of layers to form an ohmic contact.

A gate contact 116 may be formed on the upper surface of the barrier layer 112 between the source contact 114 and the drain contact 118. The material of the gate contact 116 may be chosen based on the composition of the barrier layer 112, and may, in some embodiments, be a Schottky contact. In this regard, materials capable of making a Schottky contact to a gallium nitride-based semiconductor material may be used, such as, for example, nickel (Ni), platinum (Pt), nickel silicide (NiSix), copper (Cu), palladium (Pd), chromium (Cr), tungsten (W) and/or tungsten silicon nitride (WSiN).

In some example embodiments, the material of the barrier layer, the material of the first channel layer, the material of the connecting layer, the material of the second channel layer, the material of the buffer layer, and the material of the substrate layer may be grown along a crystal axis (c-direction).

A two-dimensional electron gas (2-DEG) layer 111 is formed at a junction between the first channel layer 110 and the barrier layer 112 when the HEMT device is biased to be in its conducting or “on” state. The 2-DEG layer acts as a highly conductive layer that allows current to flow between the source and drain regions of the device that are beneath the source contact 114 and the drain contact 118, respectively. The 2-DEG layer 111 acts as a highly conductive layer that allows conduction between the source and drain regions of the device that are beneath the source contact 114 the drain contact 118, respectively. Furthermore, due to the highly conductive electron gas, the first channel layer 110 becomes negatively doped and thus forms the basis of the n-type emitter terminal of a BJT which will be described next.

FIG. 1F illustrates a sectional view of the three-dimensional structure of the bipolar junction transistor (BJT) of the compound transistor of FIG. 1A, according to some example embodiments. FIG. 1G illustrates a cross sectional view of the BJT of FIG. 1F, according to some example embodiments. The views illustrated in FIGS. 1F-1G do not show the substrate and buffer layer for the sake of brevity and to avoid repetition. Referring to FIGS. 1F and 1G, a second channel layer 106 is formed on the upper surface of the buffer layer 104 of FIG. 1A and the connecting layer 108 is formed on a portion of the upper surface of the second channel layer 106. The HEMT structure described with reference to FIGS. 1D and 1E is thereafter formed on a first portion of the upper surface of the connecting layer 108 and a base metal contact 113 is formed on a second portion of the upper surface of the connecting layer 108 such that the HEMT structure, particularly the first channel layer 110, is electrically insulated from the base metal contact 113. On another portion of the second channel layer 106, a collector electrode metal contact 120 is formed.

The second channel layer 106 and the connecting layer 108 may each be formed by epitaxial growth in some embodiments. The material formation of the second channel layer 106 may be same as that of the first channel layer 110. In some example embodiments, the second channel layer 106 may be n doped. The connecting layer may comprise a p-doped version of a Group III-nitride based material such as p-GaN. According to some example embodiments, the work-function of a material of the connecting layer 108 is greater than a work function of a material of the first channel layer 110 and a WF of a material of the second channel layer 106. The gate metal contact 116 serves as the emitter electrode for the BJT. The base metal contact 113 and the collector metal contact 120 may form an ohmic contact with the connecting layer 108 and the second channel layer 106, respectively. The biasing of the gate 116 causes the first channel layer 110 to become doped with electrons (n-doped) which serves as the emitter layer for the BJT. The p-doped connecting layer serves as the base layer for the BJT while the second channel layer 106 serves as the collector layer for the BJT.

The HEMT and the BJT are formed as a part of the same process and together they form the compound transistor 100 of FIG. 1A. The first channel layer 110 is shared between the HEMT structure and the BJT structure which saves space and simplifies the manufacturing process as well. Furthermore, in some example embodiments, the drain 118 and the collector terminal 120 are connected through a via connect such as the via connect 119 shown in FIGS. 1A and 1C. Also, the source 114 and the base metal contact 113 are connected in the manner described with reference to FIG. 1A-1C. Thus, the compound transistor 100 can be modeled as a connection of two transistors and its working is described referring to such a two-transistor model.

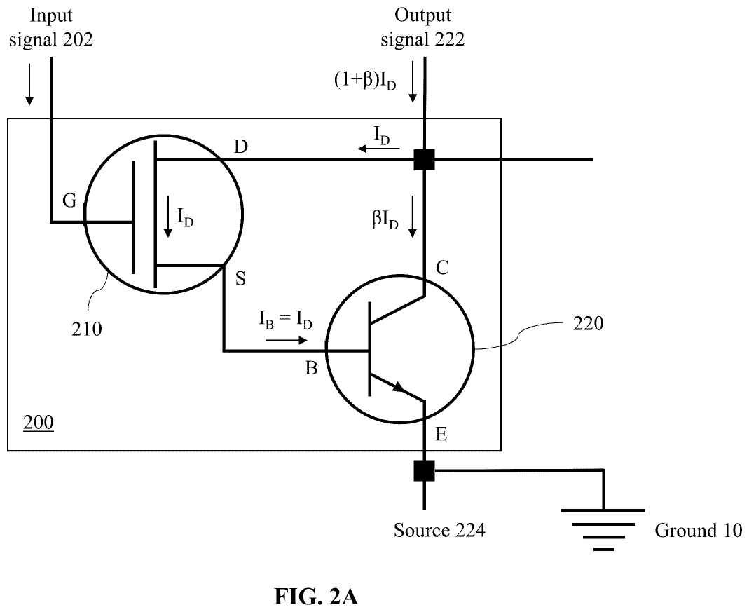

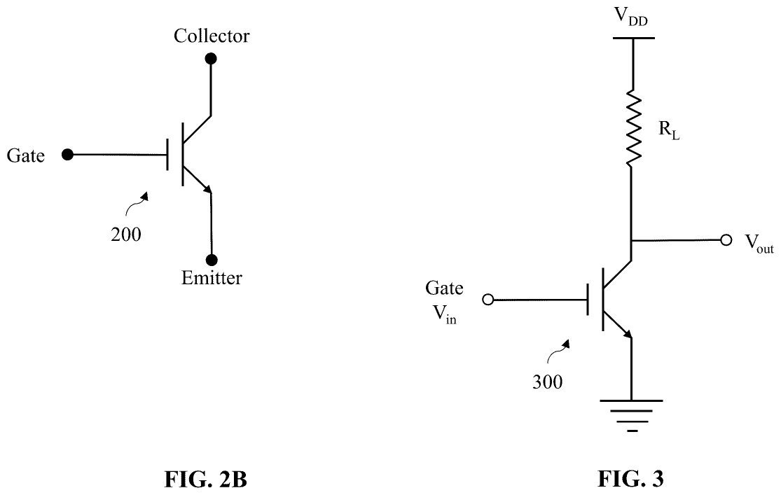

FIG. 2A illustrates one such two transistor model of the compound transistor of FIG. 1A, according to some example embodiments. The compound transistor 100 is a configuration of a HEMT 210 and a bipolar transistor 220 that operate together to amplify a signal. Such an arrangement of the transistors 210 and 220 allows for a much higher drain current and a higher input impedance compared to a single bipolar transistor configuration. The compound device 100 comprises the two transistors 210 and 220, which may also be referred to using the notation Q1 for transistor 210 and Q2 for transistor 220, that are connected in a manner as shown in FIG. 2A. The source of Q1 is connected to the base of Q2, and the emitter (source 224 of the compound device) of Q2 is connected to the ground 10. The input signal 202 is applied to the gate of Q1, and the output signal 222 is taken from the collector of Q2 and drain of Q1 which are shorted together.

The operation of the device may be understood by analyzing the behavior of the two transistors separately and then combining their effects. When a signal 202 is applied to the gate of Q1, it causes current I_{D} to flow from the drain to the source of Q1. This current acts as the base current I_{B} for Q2, i.e., I_{B}=I_{D}. As a result, an amplified current βI_{D} flows through the collector of Q2, which yields a total current of (1+β)I_{D} at the drain of the proposed compound device. In other words, the total current I_{DS} of the compound device 100 is given by

$${I}_{DS} = ( 1 + β ) {I}_{D}$$

where β is the common-emitter current gain expressed as the ratio of the bipolar transistor's collector current to the base current, and I_{D} is the drain current through the HEMT's drain electrode.

The equivalent circuit representation 200 of the compound device 100 is illustrated in FIG. 2B. The compound device 100 has a gate terminal, and a collector and emitter terminal. The compound transistor or device 100 owing to a unique structure and operational design outperforms conventional BJTs as well as HEMTs in myriad ways. For example, owing to improved current handling capabilities introduced by the improved design, some example embodiments are capable of supporting application areas where high current and high input impedance and higher switching speed are desirable. Furthermore, owing to the sharing of layers and requirement of extra substrate layer being removed for the HEMT, some example embodiments provide a compact transistor design which consumes less space yet provides significant performance improvements.

FIG. 3 illustrates circuit diagram of an inverter realized using a compound semiconductor device 300 such as the compound transistor of FIG. 2B, according to some example embodiments. Inverters are used in sorts of electronic circuits. It is the fundamental building block of a digital circuit. Apart from digital circuits, it is also used in various power electronic circuits as well. An input voltage Vin is provided at the gate of the compound semiconductor device 300. The emitter of the compound semiconductor device 300 is grounded while the collector is connected to drain voltage V_{DD} through a resistor R_{L}. The inverted output Vₒᵤₜ is taken from the collector of the compound semiconductor device 300.

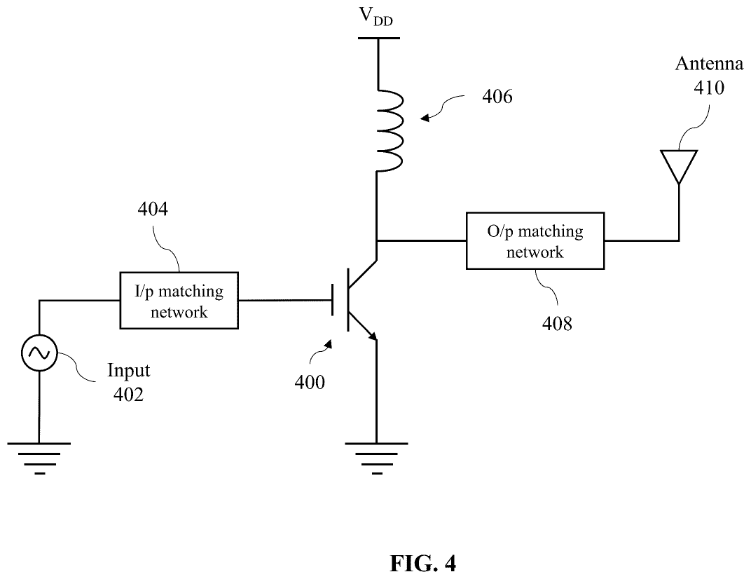

FIG. 4 illustrates circuit diagram of a power amplifier realized using a compound semiconductor device 400 such as the compound transistor of FIG. 2B, according to some example embodiments. Power amplifiers are used in all wireless communication circuits. It is an integral part of RF front end module of any cell phone as well as based stations. An input signal 402 is supplied to an input matching network 404 which is connected to the gate of the compound semiconductor device 400. The emitter terminal of the compound semiconductor device 400 is connected to the ground while the collector of the compound semiconductor device 400 is connected to the voltage V_{DD} through an inductor 406. The collector is also connected to an output matching network 408 through which a radio frequency signal is transmitted via an antenna 410. In such a configuration as illustrated in FIG. 4, the compound semiconductor device 400 amplifies the input signal 402 for transmission via the antenna 410 after it has been matched by the output matching network 408.

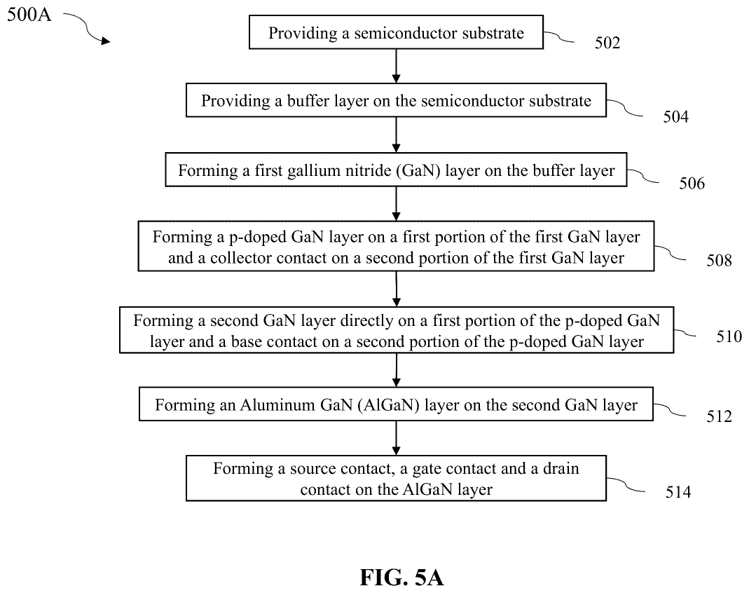

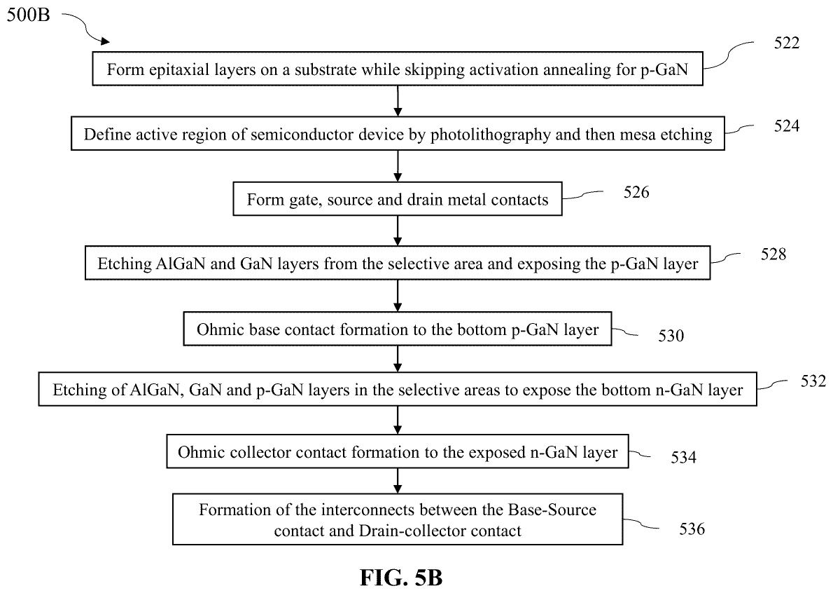

FIG. 5A illustrates a flowchart of a method 500A of manufacturing a compound semiconductor device, according to some example embodiments. The steps of the method 500A as described in FIG. 5A may be executed in any order and/or one or more steps may be executed in combination. Referring to FIG. 5A, the method 500A comprises providing 502 a semiconductor substrate such as the substrate 102 of FIG. 1A. In some example embodiments, the semiconductor substrate may be a semi-insulating silicon carbide (SiC) substrate that may be, for example, the 4H polytype of silicon carbide. The method also comprises providing 504 a buffer layer such as the layer 104 on the semiconductor substrate. The buffer layer may be grown to tackle the lattice mismatch between the wafer material and the III-N semiconductor.

A channel layer, such as the layer 106 of FIG. 1A which is made up of a suitable III-N semiconductor material such as gallium nitride (GaN), is formed 506 on the buffer layer. The channel layer may have a bottom surface, in contact with the buffer layer, and a top surface that is opposite to the bottom surface.

The method further comprises forming 508 a connecting layer, such as the connecting layer 108 of FIG. 1A, on one side of the top surface (i.e., on a first portion) of the channel layer, and a collector layer, such as the collector metal contact 120 of FIG. 1A, on another side of the top surface (i.e., a second portion) of the GaN channel layer. The connecting layer may comprise a suitable p-doped III-N semiconductor material such as p-GaN. A surface of the connecting layer that interfaces the top surface of the GaN channel layer may have a dimension that is less than that of the top surface of the GaN channel layer such that the connecting layer is always not in contact with the collector metal contact. In some example embodiments, the collector metal contact may extend laterally in a plane of the top surface of the GaN channel layer. In some alternative embodiments, the collector metal contact may extend vertically into the GaN channel layer such that the collector metal contact is orthogonal to the top surface of the GaN channel layer 106 as is shown in FIG. 1B.

The method also comprises forming 510 another channel layer (also referred to as second channel layer), such as the channel layer 110 of FIG. 1A, directly on a first portion of the connecting layer and a base contact on a second portion of the connecting layer. The second channel layer may also comprise any suitable III-N semiconductor material such as gallium nitride (GaN). A barrier layer comprising Aluminum GaN (AlGaN) is also formed 512 on the second GaN channel layer. The method further comprises forming 514 a source contact, a gate contact, and a drain contact on the AlGaN layer. The source contact, gate contact, and the drain contact are formed in a such a way that the source contact is electrically connected to the base contact but electrically isolated from the second GaN layer by an oxide deposition and the drain contact is electrically connected to the collector contact.

In some example embodiments, the method 500A may comprise additional or optional steps that are not shown in FIG. 5A. For example, the method 500A may additionally or optionally comprise connecting the drain contact with the collector contact using a via such as the via connect 119 of FIG. 1A. Further, the method 500A may additionally or optionally comprise connecting the source contact with the base contact.

Some example processes and sub-processes deployed for the formation of the compound semiconductor device of FIG. 1A are described next. FIG. 5B illustrates a flowchart of a fabrication process 500B of the compound transistor of FIG. 1A, according to some example embodiments. The epitaxial layers are formed 522 on a semiconductor substrate. Where the layers are grown on a foreign substrate, in that case appropriate buffer layers are used to manage the thermal and crystal mismatch. If the layers are grown on a GaN substrate, then the buffer layers may not be needed. The epitaxial layers may be grown using one or a combination of MOCVD, MBE or Metalorganic vapor-phase epitaxy (MOVPE) systems. If the layers are grown on MOCVD or MOVPE system, then after the growth of the layers p-GaN is activated through a prolonged annealing in nitrogen (N₂) environment. If the layers are grown using MBE method, then the activation annealing may not be required.

For the fabrication process 500B, active region is defined 524 so that each device fabricated on the same wafers are electrically isolated from each other. Such an isolation may be achieved through mesa etching or nitrogen ion implantation. N-ion implantation makes the GaN resistive, thus achieving the electrical isolation. In case of mesa isolation, active epitaxial layers are etched away using BCl₃/Cl₂ plasma. During the etching process, the active device region is protected by a thick photo resist layer. This thick photoresist layer on the active device may be patterned by photolithography.

The next subprocess in the fabrication involves forming 526 the gate contact, source contact and the drain contact. Gate contact may be formed using Ni/Au or any other high work function metal like Pt or Pd. The gate contact may be formed by one or more of photolithography and lift-off process or a metal deposition, photolithography and etch process. The second process (i.e., metal deposition, photolithography and etch) is a CMOS compatible process hence preferred over the first one (photolithography and lift-off process). After the formation of gate metal contact the source and drain ohmic contacts are formed using the similar process. For the source and the drain contacts different metal combinations may be used. In some example embodiments, a combination of Ti/Al/Ni/Au (with corresponding dimensions of 20 nm/100 nm/25 nm/50 nm respectively) may be preferred. After the metal contact formation high temperature annealing is performed to make the contacts ohmic.

Photolithography and then etching 528 of AlGaN/GaN layers using Chlorine-based plasma from the selective area to expose the p-GaN layer is then performed. During this step the photoresist acts as hard mask layer protecting the AlGaN/GaN region from being exposed to the plasma. After the etching, the base contact to the exposed p-GaN region is formed which is followed by ohmic annealing for the base contact to p-GaN to form 530 the ohmic contact to the bottom p-GaN layer. This subprocess utilizes the process mentioned in step 526. However, this time Mg/Au metal combination may be used for the contact. Annealing in N₂/02 may be done to make the contact ohmic to p-GaN.

The next subprocess utilized for the fabrication 500B includes etching 532 of AlGaN, GaN and p-GaN layers in the selective areas to expose the bottom n-GaN layer. By adopting the same process mentioned in step 528, the n-GaN layer beneath the p-GaN is exposed. A collector metal contact to the exposed n-GaN layer is formed and ohmic annealing of the collector metal contact to the exposed n-GaN layer is performed to form 534 the ohmic contact to n-GaN. For metal contacts Ti/Au metals could be used.

A passivation material such as SiNx or SiO₂ or a combination of SiNx/SiO is deposited to passivate the device. Interconnects are formed 536 between Base-Source and Drain-Collector contacts. Prior to this a via is opened through the passivation layer using photolithography to pattern and the F-based plasma etching to etch away SiNx/SiO₂.

Some or all of the subprocesses of the fabrication process 500B may be utilized for implementing the method of manufacturing 500A of the compound semiconductor device of FIG. 1A. Furthermore, in this regard additional and intermediate steps may also be implemented that are known in the art but not listed in the fabrication process.

### Definitions

According to aspects of the present disclosure, and based on experimentation, the following definitions have been established, and certainly are not complete definitions of each phrase or term. Wherein the provided definitions are merely provided as an example, based upon learnings from experimentation, wherein other interpretations, definitions, and other aspects may pertain. However, for at least a mere basic preview of the phrase or term presented, such definitions have been provided, but by “no means” can the definitions presented below be applied as prior art, since this is knowledge gained only from experimentation.

Two layers in direct contact: Two layers that are in direct contact may be understood to be an arrangement where two contacting layers have no other intervening layer(s) present. That is, a direct physical contact between the two layers.

Two-dimensional (2D) semiconductor layer: A two-dimensional (2D) semiconductor layer refers to a semiconductor layer comprising a 2D material layer. Such materials have interesting properties in terms of anisotropic mobility and therefore allow for future scaling of transistor performance. For example, in some embodiments, a 2D material layer may have a dimension in one direction that is smaller than dimensions in other orthogonal directions, such that at least one physical property in the one direction may be different compared to the physical property in the other orthogonal directions. For example, physical properties that may be direction-dependent include band gap, electrical and/or thermal conductivities, density of states, carrier mobility's, etc. For example, when a 2D material layer is formed as a sheet in a plane formed by x and y directions and has a dimension in an orthogonal z direction that is sufficiently smaller compared to dimensions in the x and y directions, the 2D material layer may have a band gap that is different, e.g., greater, than a band gap in x and/or y directions. In addition, in some embodiments, 2D material layer may be a material having a layered structure, where atoms of the 2D material layer may have one type of bonding in x and y directions while having a different type of bonding in the z direction. For example, the atoms of the 2D material layer may be covalently bonded in x and y directions while being weakly bound, e.g., by Van der Waals forces, in the z direction.

Gallium nitride (GaN): GaN is a binary III/V direct bandgap semiconductor used in light-emitting diodes. The compound is a very hard material that has a Wurtzite crystal structure. Its wide band gap of 3.4 eV affords it special properties for applications in optoelectronic, high-power and high-frequency devices. For example, GaN is the substrate which makes violet (405 nm) laser diodes possible, without use of nonlinear optical frequency-doubling. Its sensitivity to ionizing radiation is low (like other group III nitrides), making it a suitable material for solar cell arrays for satellites. Space applications could also benefit as devices have shown stability in radiation environments. Because GaN transistors can operate at much higher temperatures and work at much higher voltages than gallium arsenide (GaAs) transistors, they make ideal power amplifiers at microwave frequencies. In addition, GaN offers promising characteristics for THz devices.

The very high breakdown voltages, high electron mobility and saturation velocity of GaN has also made it an ideal candidate for high-power and high-temperature microwave applications, as evidenced by its high Johnson's figure of merit. Potential markets for high-power/high-frequency devices based on GaN include microwave radio-frequency power amplifiers (such as those used in high-speed wireless data transmission) and high-voltage switching devices for power grids. A potential mass-market application for GaN-based RF transistors is as the microwave source for microwave ovens, replacing the magnetrons currently used. The large band gap means that the performance of GaN transistors is maintained up to higher temperatures (^{˜}400° C.) than silicon transistors (^{˜}150° C.) because it lessens the effects of thermal generation of charge carriers that are inherent to any semiconductor. An enhancement-mode GaN transistors that are only n-channel transistors were designed to replace power MOSFETs in applications where switching speed or power conversion efficiency is critical. These transistors, also called eGaN FETs, can be built by growing a thin layer of GaN on top of a standard silicon wafer. Which allows the eGaN FETs to maintain costs similar to silicon power MOSFETs but with the superior electrical performance of GaN. GaN transistors can be depletion mode devices, i.e., on/resistive when a gate-source voltage is zero.

Aluminum gallium nitride (AlGaN): AlGaN is a semiconductor material and is any alloy of aluminum nitride and gallium nitride. The bandgap of AlGal-xN can be tailored from 3.4 eV (xAl=0) to 6.2 eV (xAl=1). Also, AlGaN can be used to manufacture light-emitting diodes operating in blue to ultraviolet regions, where wavelengths down to 250 nm (far UV) were achieved. AlGaN can be used in blue semiconductor lasers, used in detectors of ultraviolet radiation, and in AlGaN/GaN High-electron-mobility transistors. AlGaN can be used together with gallium nitride or aluminum nitride, forming heterojunctions. AlGaN layers can be grown on Gallium nitride, on sapphire or Si, and sometimes with additional GaN layers.

High electron mobility transistors (HEMTs): Also known as heterostructure FET (HFET) or modulation-doped FET (MODFET), is a field-effect transistor incorporating a junction between two materials with different band gaps (i.e., a heterojunction) as the channel instead of a doped region (as is generally the case for a MOSFET). A material combination can be GaN with AlGaN, though there is wide variation, dependent on the application of the device. Devices incorporating more indium generally show better high-frequency performance, gallium nitride HEMTs have high-power performance. Like other FETs, HEMTs are used in integrated circuits as digital on-off switches. FETs can also be used as amplifiers for large amounts of current using a small voltage as a control signal. Both of these uses are made possible by the FET's unique current-voltage characteristics. HEMT transistors are able to operate at higher frequencies than ordinary transistors, up to millimeter wave frequencies, and are used in high-frequency products such as cell phones, satellite television receivers, voltage converters, and radar equipment. They are used in satellite receivers, in low power amplifiers and in the defense industry. Some advantages of HEMTs can be that they have high gain, this makes them useful as amplifiers; high switching speeds, which are achieved because the main charge carriers in MODFETs are majority carriers, and minority carriers are not significantly involved; and extremely low noise values because the current variation in these devices is low compared to other FETs. HEMTs are heterojunctions. This means that the semiconductors used have dissimilar band gaps. For instance, silicon has a band gap of 1.1 electron volts (eV), while germanium has a band gap of 0.67 eV. When a heterojunction is formed, the conduction band and valence band throughout the material must bend in order to form a continuous level.

The HEMTs' exceptional carrier mobility and switching speed come from the following conditions: The wide band element is doped with donor atoms; thus, it has excess electrons in its conduction band. These electrons will diffuse to the adjacent narrow band material's conduction band due to the availability of states with lower energy. The movement of electrons will cause a change in potential and thus an electric field between the materials. The electric field will push electrons back to the wide band element's conduction band. The diffusion process continues until electron diffusion and electron drift balance each other, creating a junction at equilibrium similar to a p-n junction. Note that the undoped narrow band gap material now has excess majority charge carriers. The fact that the charge carriers are majority carriers yields high switching speeds, and the fact that the low band gap semiconductor is undoped means that there are no donor atoms to cause scattering and thus yields high mobility.

An important aspect of HEMTs is that the band discontinuities across the conduction and valence bands can be modified separately. This allows the type of carriers in and out of the device to be controlled. As HEMTs require electrons to be the main carriers, a graded doping can be applied in one of the materials, thus making the conduction band discontinuity smaller and keeping the valence band discontinuity the same. This diffusion of carriers leads to the accumulation of electrons along the boundary of the two regions inside the narrow band gap material. The accumulation of electrons leads to a very high current in these devices. The accumulated electrons are also known as 2DEG or two-dimensional electron gas. The term “modulation doping” refers to the fact that the dopants are spatially in a different region from the current carrying electrons.

To allow conduction, semiconductors are doped with impurities which donate either mobile electrons or holes. However, these electrons are slowed down through collisions with the impurities (dopants) used to generate them in the first place. HEMTs avoid this through the use of high mobility electrons generated using the heterojunction of a highly doped wide-bandgap n-type donor-supply layer (AlGaN in our example) and a non-doped narrow-bandgap channel layer with no dopant impurities (GaN in this case). The electrons generated in the thin n-type AlGaN layer drop completely into the GaN layer to form a depleted AlGaN layer, because the heterojunction created by different band-gap materials forms a quantum well (a steep canyon) in the conduction band on the GaN side where the electrons can move quickly without colliding with any impurities because the GaN layer is undoped, and from which they cannot escape. The effect of this is to create a very thin layer of highly mobile conducting electrons with very high concentration, giving the channel very low resistivity (or to put it another way, “high electron mobility”). Further, HEMTs based on AlGaN/GaN heterostructures present excellent candidates for high-power, high-voltage and high-temperature applications.

Depletion-mode (D-mode) HEMTs: In field effect transistors (FETs), depletion mode and enhancement mode are two major transistor types, corresponding to whether the transistor is in an ON state or an OFF state at zero gate-source voltage. Enhancement-mode MOSFETs (metal-oxide-semiconductor FETs) are the common switching elements in most integrated circuits. These devices are off at zero gate-source voltage. NMOS can be turned on by pulling the gate voltage higher than the source voltage, PMOS can be turned on by pulling the gate voltage lower than the source voltage. In most circuits, this means pulling an enhancement-mode MOSFET's gate voltage towards its drain voltage turns it ON. In a depletion-mode MOSFET, the device is normally ON at zero gate-source voltage. Such devices are used as load “resistors” in logic circuits (in depletion-load NMOS logic, for example). For N-type depletion-load devices, the threshold voltage might be about −3 V, so it could be turned off by pulling the gate 3 V negative (the drain, by comparison, is more positive than the source in NMOS). In PMOS, the polarities are reversed. The mode can be determined by the sign of the threshold voltage (gate voltage relative to source voltage at the point where an inversion layer just forms in the channel): for an N-type FET, enhancement-mode devices have positive thresholds, and depletion-mode devices have negative thresholds; for a P-type FET, enhancement-mode negative, depletion-mode positive.

Two-dimensional electron gas (2-DEG): 2DEG is a scientific model in solid-state physics. It is an electron gas that is free to move in two dimensions, but tightly confined in the third. This tight confinement leads to quantized energy levels for motion in the third direction, which can then be ignored for most problems. Thus, the electrons appear to be a 2D sheet embedded in a 3D world. The analogous construct of holes is called a two-dimensional hole gas (2DHG), and such systems have many useful and interesting properties.

Most 2DEG are found in transistor-like structures made from semiconductors. The most commonly encountered 2DEG is the layer of electrons found in MOSFETs (metal-oxide-semiconductor field-effect transistors). When the transistor is in inversion mode, the electrons underneath the gate oxide are confined to the semiconductor-oxide interface, and thus occupy well defined energy levels. For thin-enough potential wells and temperatures not too high, only the lowest level is occupied (see the figure caption), and so the motion of the electrons perpendicular to the interface can be ignored. However, the electron is free to move parallel to the interface, and so is quasi-two-dimensional.

For engineering, 2DEGs are high-electron-mobility-transistors (HEMTs) and rectangular quantum wells. HEMTs are field-effect transistors that utilize the heterojunction between two semiconducting materials to confine electrons to a triangular quantum well. Electrons confined to the heterojunction of HEMTs exhibit higher mobilities than those in MOSFETs, since the former device utilizes an intentionally undoped channel thereby mitigating the deleterious effect of ionized impurity scattering. Two closely spaced heterojunction interfaces may be used to confine electrons to a rectangular quantum well. Careful choice of the materials and alloy compositions allow control of the carrier densities within the 2DEG.

Electrons may also be confined to the surface of a material. For example, free electrons will float on the surface of liquid helium, and are free to move along the surface, but stick to the helium; some of the earliest work in 2DEGs was done using this system. Besides liquid helium, there are also solid insulators (such as topological insulators) that support conductive surface electronic states.

For simplicity and clarity of the illustration(s), elements in the figures are not necessarily to scale, some of the elements may be exaggerated for illustrative purposes, and the same reference numbers in different figures denote the same elements, unless stated otherwise. Additionally, descriptions and details of well-known steps and elements may be omitted for simplicity of the description. As used herein current carrying element or current carrying electrode means an element of a device that carries current through the device such as a source or a drain of an MOS transistor or an emitter or a collector of a bipolar transistor or a cathode or anode of a diode, and a control element or control electrode means an element of the device that controls current through the device such as a gate of an MOS transistor or a base of a bipolar transistor. Additionally, one current carrying element may carry current in one direction through a device, such as carry current entering the device, and a second current carrying element may carry current in an opposite direction through the device, such as carry current leaving the device. Although the devices may be explained herein as certain N-channel or P-channel devices, or certain N-type or P-type doped regions, a person of ordinary skill in the art will appreciate that complementary devices are also possible in accordance with the present invention. One of ordinary skill in the art understands that the conductivity type refers to the mechanism through which conduction occurs such as through conduction of holes or electrons, therefore, that conductivity type does not refer to the doping concentration but the doping type, such as P-type or N-type. It will be appreciated by those skilled in the art that the words during, while, and when as used herein relating to circuit operation are not exact terms that mean an action takes place instantly upon an initiating action but that there may be some small but reasonable delay(s), such as various propagation delays, between the reaction that is initiated by the initial action. Additionally, the term while means that a certain action occurs at least within some portion of a duration of the initiating action. The use of the word approximately or substantially means that a value of an element has a parameter that is expected to be close to a stated value or position. However, as is well known in the art there are always minor variances that prevent the values or positions from being exactly as stated. It is well established in the art that variances of up to at least ten percent (10%) (and up to twenty percent (20%) for some elements including semiconductor doping concentrations) are reasonable variances from the ideal goal of exactly as described. When used in reference to a state of a signal, the term “asserted” means an active state of the signal and the term “negated” means an inactive state of the signal. The actual voltage value or logic state (such as a “1” or a “0”) of the signal depends on whether positive or negative logic is used. Thus, asserted can be either a high voltage or a high logic or a low voltage or low logic depending on whether positive or negative logic is used and negated may be either a low voltage or low state or a high voltage or high logic depending on whether positive or negative logic is used. Herein, a positive logic convention is used, but those skilled in the art understand that a negative logic convention could also be used. The terms first, second, third and the like in the claims or/and in the Detailed Description of the Drawings, as used in a portion of a name of an element are used for distinguishing between similar elements and not necessarily for describing a sequence, either temporally, spatially, in ranking or in any other manner. It is to be understood that the terms so used are interchangeable under appropriate circumstances and that the embodiments described herein are capable of operation in other sequences than described or illustrated herein. Reference to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment, but in some cases it may. Furthermore, the particular features, structures, or characteristics may be combined in any suitable manner, as would be apparent to one of ordinary skill in the art, in one or more embodiments. For clarity of the drawings, doped regions of device structures are illustrated as having generally straight-line edges and precise angular corners. However, those skilled in the art understand that due to the diffusion and activation of dopants the edges of doped regions generally may not be straight lines and the corners may not be precise angles.

In addition, the description of one or more embodiments may illustrate a cellular design (where the body regions are a plurality of cellular regions) instead of a single body design (where the body region is comprised of a single region formed in an elongated pattern, typically in a serpentine pattern). However, it is intended that the description is applicable to both a cellular implementation and a single base implementation.

The embodiments illustrated and described hereinafter suitably may have embodiments and/or may be practiced in the absence of any element which is not specifically disclosed herein. The foregoing description provides exemplary embodiments only, and is not intended to limit the scope, applicability, or configuration of the disclosure. Rather, the description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicate like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be rearranged. A process may be terminated when its operations are completed but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

What is claimed is:

1. A compound transistor, comprising:
a plurality of electrodes forming a source, a gate, and a drain of a first transistor of the compound transistor;
a first semiconductor structure electrically connected to the plurality of electrodes, the first semiconductor structure including a barrier layer and a first channel layer with materials forming heterojunction for carrying a charge between the source and the drain in the first transistor;
a second semiconductor structure arranged to support the first semiconductor structure, the second semiconductor structure including a second channel layer, a buffer layer, and a substrate layer arranged such that the buffer layer is sandwiched between the second channel layer and the substrate layer;
a connecting layer arranged between the first and the second semiconductor structures; and
a source electrode electrically connected to the second channel layer of the second semiconductor structure such that the source of the first transistor forms a base of a second transistor, and the source electrode forms a collector of the second transistor.

2. The compound transistor of claim 1, wherein a work-function (WF) of a material of the connecting layer is greater than a WF of a material of the first channel layer and a WF of a material of the second channel layer.

3. The compound transistor of claim 1, wherein at least one dimension of the second semiconductor structure is greater than a width of the first semiconductor structure.

4. The compound transistor of claim 1, wherein the source of the first transistor has a structure defined by a first leg and a second leg, wherein the first leg is connected to the second leg and is parallel to a longitudinal extension of the drain, and wherein the second leg is parallel to a longitudinal extension of the source electrode.

5. The compound transistor of claim 4, wherein the first leg of the source is connected to the second leg with a step such that the first leg is arranged in a first plane that lies at the top of the first semiconductor structure, and the second leg is connected to the first leg in a second plane that lies at the bottom of the first semiconductor structure and is on the connecting layer.

6. The compound transistor of claim 5,
wherein a width of the connecting layer is greater than a width of the first semiconductor structure such that the connecting layer supports the second leg, and
wherein a width of the second semiconductor structure is greater than the width of the connecting layer such that the second semiconductor structure supports the source electrode.

7. The compound transistor of claim 1,
wherein a material of the barrier layer includes one or more of AlGaN, AlInN, AlInGaN, AlN, ScAlN;
wherein a material of the first channel layer includes GaN;
wherein a material of the connecting layer includes one or more of p-GaN, p-InGaN;
wherein a material of the second channel layer includes GaN;
wherein a material of the buffer layer includes one or a combination of C-doped GaN, Fe-doped GaN material; and
wherein a material of the substrate layer includes one or a combination of Si, SiC, GaN, Sapphire, a Coefficients of Thermal Expansion (CTE) matched—AlN material.

8. The compound transistor of claim 7, wherein the material of the barrier layer, the material of the first channel layer, the material of the connecting layer, the material of the second channel layer, the material of the buffer layer, and the material of the substrate layer are grown along a crystal axis c-direction.

9. The compound transistor of claim 7, wherein the material of the barrier layer, the material of the first channel layer, the material of the connecting layer, the material of the second channel layer, the material of the buffer layer, and the material of the substrate layer belong to III-N group.

10. The compound transistor of claim 7, wherein the material of the barrier layer, the material of the first channel layer, the material of the connecting layer, the material of the second channel layer, the material of the buffer layer, and the material of the substrate layer are grown using at least one of MOCVD, MBE, and HVPE.

11. An apparatus, comprising:
a high electron mobility transistor (HEMT) comprising a barrier layer and a channel layer such that there is an accumulation of two-dimensional gas (2-DEG) at an interface of the barrier layer and the channel layer in an on state of the HEMT; and
a bipolar junction transistor (BJT) structurally coupled to the HEMT such that a source of the HEMT is electrically coupled to a base of the BJT and the channel layer of the HEMT forms an emitter layer of the BJT.

12. The apparatus of claim 11, wherein a drain of the HEMT is electrically coupled to a collector of the BJT.

13. The apparatus of claim 11, wherein the HEMT is operable to provide an input current at the source in the on state of the HEMT and provide zero current at the source in an off state of the HEMT, and wherein the BJT is operable to amplify the input current in an on state of the BJT.

14. The apparatus of claim 11, wherein the accumulation of the 2-DEG causes doping of the channel layer of the HEMT with charge carriers thereby forming the emitter layer of the BJT.

15. The apparatus of claim 11, wherein the HEMT and the BJT have a common substrate layer.

16. The apparatus of claim 15, wherein the HEMT has a first multi-layered semiconductor structure and the BJT has a second multi-layered semiconductor structure with the channel layer commonly shared between the first multi-layered semiconductor structure and the second multi-layered semiconductor structure.

17. The apparatus of claim 16, wherein the second multi-layered semiconductor structure is directly on top of the common substrate layer and the first multi-layered semiconductor structure is directly on top of the second multi-layered semiconductor structure.

18. A method of manufacturing a compound semiconductor device, comprising:
providing a semiconductor substrate;
providing a buffer layer on the semiconductor substrate;
forming a first gallium nitride (GaN) layer on the buffer layer;
forming a p-doped GaN layer on a first portion of the first GaN layer and a collector contact on a second portion of the first GaN layer;
forming a second GaN layer directly on a first portion of the p-doped GaN layer and a base contact on a second portion of the p-doped GaN layer;
forming an aluminum GaN (AlGaN) layer on the second GaN layer; and
forming a source contact, a gate contact and a drain contact on the AlGaN layer such that the source contact is electrically connected to the base contact and electrically isolated from the second GaN layer by an oxide deposition and the drain contact is electrically connected to the collector contact.
